(19) United States
(12) Patent Application Publication
(10) Pub. No.: US 2017/0346005 A1
(43) Pub. Date: Nov. 30, 2017

(54) Rare-Earth Metal Oxide Resistive Random Access Non-Volatile Memory Device

(71) Applicants: IMEC VZW, Leuven (BE); Katholieke Universiteit Leuven, KU LEUVEN R&D, Leuven (BE)

(72) Inventors: Ludovic Goux, Hannuit (BE); Andrea Fantini, Leuven (BE); Chao-Yang Chen, Leuven (BE)

(73) Assignees: IMEC VZW, Leuven (BE); Katholieke Universiteit Leuven, KU LEUVEN R&D, Leuven (BE)

(21) Appl. No.: 15/165,903

(22) Filed: May 26, 2016

(51) Int. Cl. H01L 45/00

(52) U.S. Cl. CPC H01L 45/146; H01L 45/1616; H01L 45/1233; H01L 45/1253

(57) ABSTRACT

A Resistive Random Access Memory (RRAM) device and a method of its manufacture are disclosed. The RRAM device comprises a lower oxygen affinity bottom electrode, a hygroscopic solid-state dielectric layer, comprising hydroxyl groups, and a higher oxygen affinity top electrode. In some embodiments, the hygroscopic solid-state dielectric layer is a rare-earth metal oxide layer.

### FIELD OF THE DISCLOSURE

The present disclosure is related to Resistive Random Access non-volatile Memory devices, also known as RRAIVI or ReRAM. In particular the disclosure relates to RRAM devices comprising a rare-earth metal oxide layer.

### BACKGROUND

A non-volatile RRAM device comprises a dielectric solid-state layer sandwiched between a top and a bottom electrode. Information is stored in the RRAM device by reversibly switching the electrical resistance of the device between a low resistive state (LRS), also known as on-resistance (Ron) and a high resistive state (HRS), also known as off-resistance (Roff). This switching of the electrical resistance is done using an electrical current or voltage, respectively creating or disrupting conductive filament paths in the dielectric layer. A characteristic of such RRAM is the ratio between its high resistive state (LRS) and its low resistive state (HRS), which ratio is known as the memory window.

Oxygen-vacancy based RRAIVI technology uses an oxide layer as the solid-state dielectric layer. When switching the device to the low resistive state, i.e. setting the device, a chain of oxygen-vacancy (Vo) defects is created along such conductive filament (CF). Switching the device to the high resistive state, i.e. resetting the device, corresponds to the annihilation of these defects by the recombination of oxygen and oxygen-vacancies, i.e. O-Vo recombination. The resistance value of the low resistive state is controlled by the set programming current, while the resistance value of the high resistive state is controlled by the reset programming voltage.

For an optimum bipolar-switching operation of the oxygen-vacancy based RRAM device, asymmetric devices are typically used. One electrode shows a higher oxygen affinity, while the opposite electrode shows a lower oxygen affinity. This difference in oxygen affinity between the two electrodes results in an oxygen-vacancy profile from the lower oxygen affinity electrode towards the higher oxygen affinity electrode, also known as oxygen scavenging electrode. Most of such RRAM devices use TiN, TaN, or Ru as the low-affinity electrode and Ti, Hf, or Ta as the oxygen-scavenging electrode. These choices of electrode metal make such devices more CMOS compatible. The oxide layer in-between the two electrodes is most often a transition-metal oxide layer, such as TiO₂, Ta₂O₅ or HfO₂. In an example embodiment, the metal of this oxide layer is also used to form the oxygen-scavenging electrode, e.g. a Ta-electrode is formed on a Ta₂O₅ oxide layer.

In such oxygen-vacancy based RRAM technology, the recovery of the oxygen-vacancy (Vo) defects during reset, i.e. the recombination of the oxygen and the oxygen-vacancy, improves with increasing reset voltage. However this recovery remains limited resulting in a saturation of the high resistive state at a given level. Due to this saturation, typical RRAM devices may show a typical limited memory window of about 10 for an operating set current of 50 uA.

The set-reset programming cycle involves the motion of O— species at each programming cycle. This mechanism degrades with the number of programming cycles performed. Typical state-of-the-art RRAM devices operated at a set current 50 uA may show endurance failure even after 10⁸ set-reset cycles.

### SUMMARY

The present disclosure aims to disclose a RRAM device which does not suffer from the deficiencies of conventional devices. It aims to disclose a RRAM device with increased memory window. In particular it is an aim to disclose a RRAM device with increased endurance lifetime.

In an aspect, a Resistive Random Access Memory device is provided. The device includes a lower oxygen affinity bottom electrode, a hygroscopic solid-state dielectric layer, and a higher oxygen affinity top electrode. The hygroscopic solid-state dielectric layer includes at least one hydroxyl group.

In an aspect, a method of manufacturing a Resistive Random Access Memory device is provided. The method of manufacturing includes providing a lower oxygen affinity bottom electrode. The method of manufacturing also includes forming, via atomic-layer deposition, a hygroscopic solid-state dielectric layer. The hygroscopic solid-state dielectric layer includes at least one hydroxyl group. The method of manufacturing additionally includes providing a higher oxygen affinity top electrode.

Particular aspects of the disclosure are set out in the accompanying independent and dependent claims. Features from the dependent claims may be combined with features of the independent claims and with features of other dependent claims as appropriate and not merely as explicitly set out in the claims.

These and other aspects of the disclosure will be apparent from and elucidated with reference to the embodiment(s) described hereinafter.

### BRIEF DESCRIPTION OF THE FIGURES

For the purpose of teaching, drawings are added. These drawings illustrate some aspects and embodiments of the disclosure. They are only schematic and non-limiting. The size of some of the elements may be exaggerated and not drawn on scale for illustrative purposes. The dimensions and the relative dimensions do not correspond to actual reductions to practice of the disclosure. Like features are given the same reference number.

FIG. 1 illustrates a schematic cross-section of a RRAM device according to this disclosure.

FIG. 2 illustrates a schematic cross-section of another RRAM device according to this disclosure.

FIG. 3 illustrates a schematic cross-section of a RRAM device according to an exemplary embodiment.

FIG. 4 shows the benchmarking of memory window vs endurance lifetime of the RRAM device of FIG. 3 with conventional RRAM devices.

FIG. 5 shows the benchmarking of the memory window vs pulse width of the RRAM device of FIG. 3 with conventional RRAM devices.

### DETAILED DESCRIPTION

The present disclosure will be described with respect to particular embodiments and with reference to certain drawings but the disclosure is not limited thereto. Furthermore, the terms first, second and the like in the description, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein. Moreover, the terms top, under and the like in the description are used for descriptive purposes and not necessarily for describing relative positions. It is to be understood that the terms so used are interchangeable under appropriate circumstances and that the embodiments of the disclosure described herein are capable of operation in other orientations than described or illustrated herein.

In this disclosure a RRAM device is presented providing improved reliability at low-current operation. The programming current Ip can be less than 50 pA, typically less than 10 pA, at a pulse width PW of less than 100us, typically less than 10 us. This improvement in reliability is seen inter alfa by the larger memory window even when multiple set-reset cycles are performed. The RRAM device allows a deep reset as the self-limiting character of the reset mechanism is mitigated. The degradation of the switching control at these low programming currents due to the low number of oxygen-vacancy defects involved in the switching mechanisms.

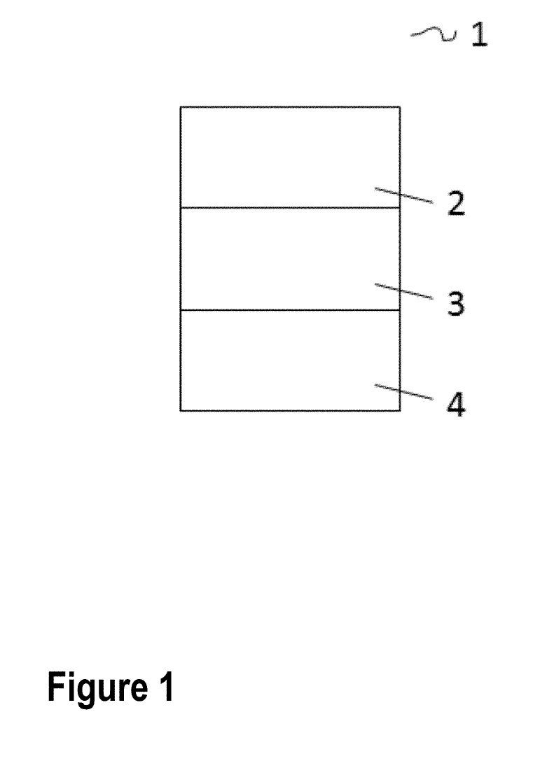

FIG. 1 shows a schematic cross-section of an oxygen-vacancy based RRAIVI device 1 according to this disclosure. The device comprises a solid-state metal oxide layer 3 in-between a top, higher oxygen-affinity, electrode 2 and a bottom, lower oxygen-affinity, electrode 4. This difference in oxygen affinity between the two electrodes results in an oxygen-vacancy profile from the lower oxygen affinity electrode towards the higher oxygen affinity electrode. Hence an asymmetric device is obtained improving bipolar switching thereof

The metal oxide layer 3 is hygroscopic and comprises hydroxyl groups (OH—). One aspect of using (OH—) groups as active species is that they are much faster and more reactive than e.g. O₂—. These hydroxyl groups improve hence the efficiency of the reset switching whereby oxygen vacancies (Vo) recombine with oxygen species thereby annihilating the defects in the conductive filament formed in the dielectric layer 3. They increase the saturation level of the high resistance state reached after reset compared to conventional RRAM devices. Thus, by controllably embedding (OH—) species in the oxide layer 3, the memory window of the RRAM device 1 can be improved. Also the endurance performance of the RRAM device 1 may be improved by this change in active species in the switching mechanism from O-based species to OH— based species.

These hydroxyl groups are controllably embedded in the metal oxide layer during formation thereof. Thanks to the hygroscopic nature of the metal oxide layer, the hydroxyl groups readily adsorb during the metal oxide layer formation and remain embedded in this metal oxide layer even after the completion of the RRAM device. Depending on the concentration of the hygroscopic material in the metal oxide layer 3 a more thermodynamically stable material configuration is obtained resulting in an improved control of the hydroxyl concentration.

In an example embodiment, the metal oxide layer 3 is a rare-earth metal oxide layer having hygroscopic properties. For example, the metal oxide layer 3 may include a Gadolinium-Oxide layer.

This rare-earth metal oxide layer 3 can be doped with Aluminum (Al) or Silicon (Si). In some embodiments, this doping is in the range from above 0 to about 50 atomic percent. In an example embodiment, this doping is in the range from above 0 to about 30 atomic percent. Doping the rare-earth metal layer may increase the electrical resistance of the metal oxide layer 3. For example an Aluminum doped Gadolinium-oxide layer, such as Al-doped Gd₂O₃, can be used as metal-oxide layer 3, whereby the Aluminum concentration ranges from above 0 to about 30 atomic percent.

Typically, metals such as TiN or TaN are used as metal for the lower oxygen affinity electrode 4 of the device illustrated by FIG. 1. In an example embodiment, the lower oxygen affinity electrode 4 may be formed from a metal having an even lower oxygen affinity than TiN or TaN. The lower the oxygen affinity of the bottom electrode 3, the more the endurance lifetime may be increased. Examples of such metals are Iridium, Iridium Oxide, Ruthenium, Ruthenium Oxide and Platinum. These metals have the further attribute that they are hydrogen catalysts. As such, they further improve the reset efficiency and hence the memory window of the RRAM device 1.

Typically, metals such as Ti, Hf or Ta are used as metal for the higher oxygen affinity electrode 2. In this respect, Ti is may be used instead of Hf or Ta. However, in order to further improve the lifetime of the RRAM device 1, a more hygroscopic scavenging material can be used. Such a material may retain the hydroxyl groups closer to the higher oxygen affinity electrode 2, thereby retarding the shift in the low resistance state when cycling the device 1. A reduced low resistance state retention loss may hence be obtained.

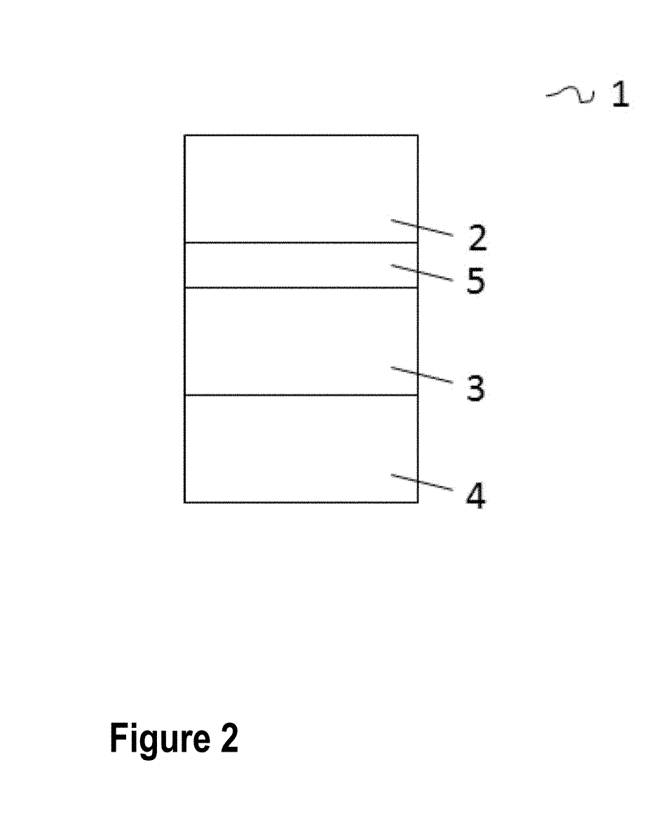

In an example embodiment, a rare earth metal is used to form the higher oxide affinity electrode as it is the rare earth metal that provides the hygroscopic property. In some embodiments, this rare earth metal is the metal of the metal oxide layer 3. For example: a layer 5 of Gadolinium can be present in between a Gadolinium-oxide layer 3 and the higher oxygen affinity electrode 2.

Whereas in FIG. 1 the material of the higher oxide affinity electrode was modified to increase the oxygen scavenging properties thereof, alternatively an additional scavenging layer 5 may be inserted in between the electrode 2 and the metal oxide layer 3 as illustrated by FIG. 2. This scavenging layer also retains the hydroxyl groups closer to electrode 2. In an example embodiment, a layer of a rare earth metal is used. In some embodiment, this scavenging layer 5 is formed from the rare earth metal of the metal oxide layer 3. For example: a layer 5 of Gadolinium can be present in between a Gadolinium-oxide layer 3 and the higher oxygen affinity electrode 2.

In an exemplary embodiment a Gadolinium-oxide layer, such as Gd₂O₃, is used as metal oxide layer 3. This layer can be doped with Aluminum and/or Silicon. Typically this doping is in the range from above 0 to about 30 atomic percent.

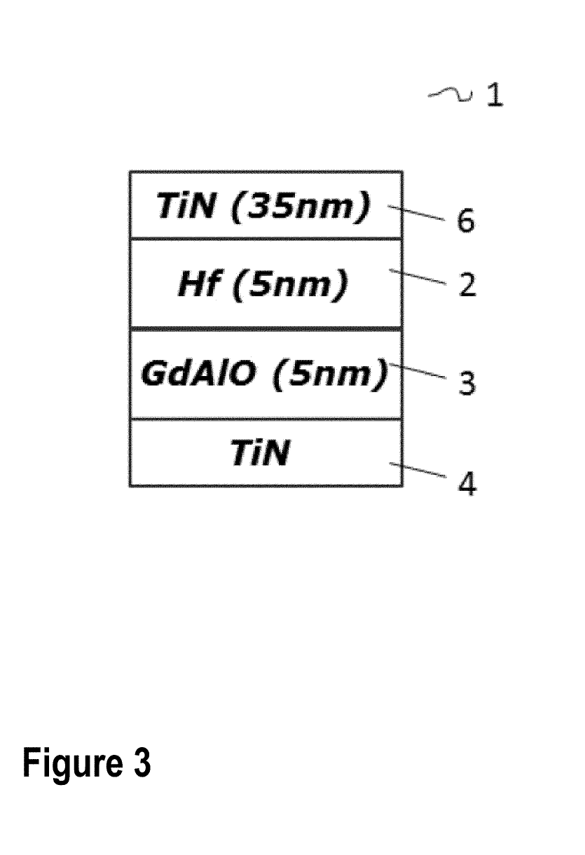

In an exemplary embodiment 5 nm-thick hygroscopic oxide layer 3 were formed by atomic-layer deposition (ALD). The oxide layer 3 was integrated between a TiN 4 and a Hf 2 electrode, as shown in FIG. 3, in 1-Transistor/1-Resistor configuration. On the Hf electrode 2 a TiN contact electrode 6 is formed. Using industry-relevant programming current (Ip)≦10 μA and pulse-width (PW)≦10 μs, the 40nm-sized TiN\Gd—Al—O\Hf cells allowed reaching a median memory window (MW) of more than 50. In a similar device configuration, conventional materials only exhibited a MW<×10 for the same operating conditions. Based on the large MW and good write endurance properties (>10⁶ cycles) of Gd—Al—O based cells, verify algorithms allowed reliable programming with low latency. The disclosed device exhibited fast switching characteristics, i.e. between 0 s and 10 μs, typically about 1 μs.

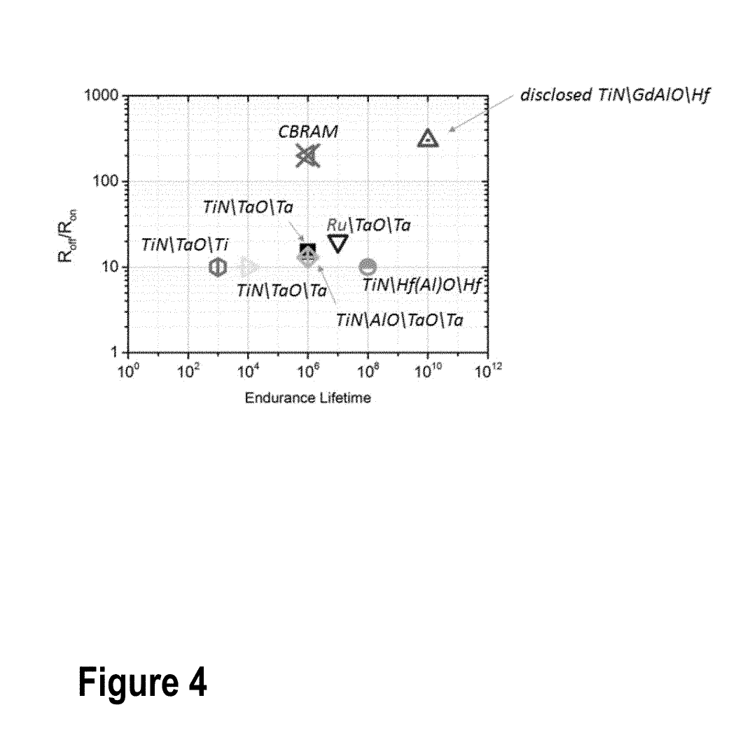

As shown in FIG. 4, the memory window and the endurance lifetime of the device of FIG. 3, measured using a programming current of 50 μA for a pulse width of 100 ns and optimized voltage conditions, is substantially larger than of conventional devices.

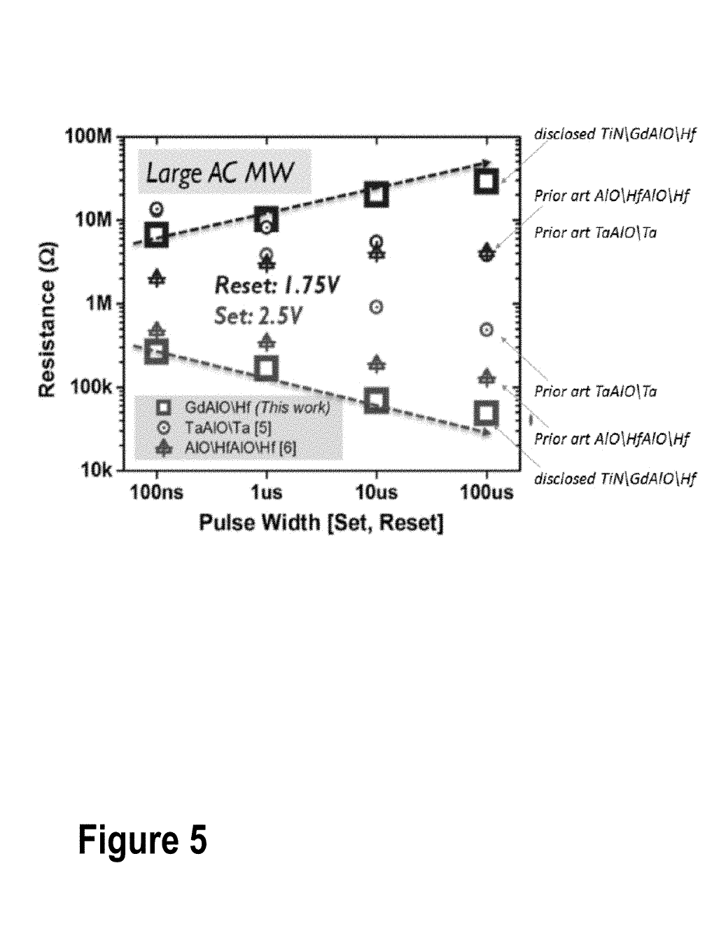

FIG. 5 shows the change in resistance of the low resistive state (LRS, set) and the high resistive state (HRS, reset) with reduced pulse width. The device of FIG. 3 maintained a lower on-resistance (LRS) and higher off-resistance (HRS) compared to conventional devices.

1. A Resistive Random Access Memory device comprising:
a lower oxygen affinity bottom electrode;
a hygroscopic solid-state dielectric layer, wherein the hygroscopic solid-state dielectric layer comprises at least one hydroxyl group; and
a higher oxygen affinity top electrode.

2. The device of claim 1, wherein the hygroscopic solid-state dielectric layer comprises a rare earth metal oxide layer, wherein the rare earth metal oxide layer comprises a dopant with a dopant range between 0 and 50 atomic percent, wherein the dopant comprises at least one of Aluminum or Silicon.

3. The device according to claim 2, wherein the dopant range is between 0 and 30 atomic percent.

4. The device according to claim 3, wherein the higher oxygen affinity top electrode comprises a rare earth metal.

5. The device according to claim 4, wherein the rare earth metal oxide layer of the hygroscopic solid-state dielectric layer comprises a same rare earth metal as the rare earth metal of the higher oxygen affinity top electrode.

6. The device according to claim 1, wherein the lower oxygen affinity bottom electrode comprises a material selected from the group of: Platinum, Iridium, Iridium Oxide, Ruthenium, and Ruthenium Oxide, or a combination thereof.

7. The device according to claim 6, wherein the higher oxygen affinity top electrode comprises a material selected from the group of: Titanium, Hafnium, and Tantalum.

8. The device according to claim 1, wherein the higher oxygen affinity top electrode comprises a rare earth metal.

9. The device according to claim 8, wherein the rare earth metal oxide layer of the hygroscopic solid-state dielectric layer comprises a same rare earth metal as the rare earth metal of the higher oxygen affinity top electrode.

10. The device according to claim 1, wherein the rare earth metal oxide layer of the hygroscopic solid-state dielectric layer comprises Gadolinium Oxide (Gd₂O₃).

11. The device according to claim 1, further comprising a top contact on the higher oxygen affinity top electrode, wherein the lower oxygen affinity bottom electrode comprises Titanium Nitride, wherein the hygroscopic solid-state dielectric layer comprises Gadolinium Aluminum Oxide, wherein the higher oxygen affinity top electrode comprises Hafnium, and wherein the top contact comprises Titanium Nitride.

12. A method of manufacturing a Resistive Random Access Memory device, comprising:
providing a lower oxygen affinity bottom electrode;
forming, via atomic-layer deposition, a hygroscopic solid-state dielectric layer, wherein the hygroscopic solid-state dielectric layer comprises at least one hydroxyl group; and
providing a higher oxygen affinity top electrode.

13. The method of manufacturing according to claim 12, wherein the hygroscopic solid-state dielectric layer comprises a rare earth metal oxide layer, wherein the rare earth metal oxide layer comprises a dopant with a dopant range between 0 and 50 atomic percent, wherein the dopant comprises at least one of Aluminum or Silicon.

14. The method of manufacturing according to claim 13, wherein the dopant range is between 0 and 30 atomic percent.

15. The method of manufacturing according to claim 12, wherein the higher oxygen affinity top electrode comprises a rare earth metal.

16. The method of manufacturing according to claim 15, wherein the rare earth metal oxide layer of the hygroscopic solid-state dielectric layer comprises a same rare earth metal as the rare earth metal of the higher oxygen affinity top electrode.

17. The method of manufacturing according to claim 12, wherein the lower oxygen affinity bottom electrode comprises a material selected from the group of: Platinum, Iridium, Iridium Oxide, Ruthenium, and Ruthenium Oxide, or a combination thereof.

18. The method of manufacturing according to claim 12, wherein the higher oxygen affinity top electrode comprises a material selected from the group of: Titanium, Hafnium, and Tantalum.

19. The method of manufacturing according to claim 12, wherein the lower oxygen affinity bottom electrode comprises Titanium Nitride, wherein the hygroscopic solid-state dielectric layer comprises Gadolinium Aluminum Oxide, and wherein the higher oxygen affinity top electrode comprises Hafnium.

20. The method of manufacturing according to claim 19, further comprising a top contact on the higher oxygen affinity top electrode wherein the top contact comprises Titanium Nitride.
